(19) United States
(12) Patent Application Publication
(10) Pub. No.: US 2018/0341281 A1
(43) Pub. Date: Nov. 29, 2018

(54) TEMPERATURE CONTROL OF COMPONENTS ON A SUBSTRATE

(71) Applicant: Texas Instruments Incorporated, Dallas, TX (US)

(72) Inventors: Roozbeh Parsa, Portola Valley, CA (US); Ann Gabrys, Woodside, CA (US); Iouri N. Mirgorodski, Sunnyvale, CA (US)

(73) Assignee: Texas Instruments Incorporated, Dallas, TX (US)

(21) Appl. No.: 15/602,376

(22) Filed: May 23, 2017

(51) Int. Cl. G05D 23/19; H01L 23/36; H01L 23/373; H05K 1/02; H05K 7/20

(52) U.S. Cl. CPC G05D 23/19; H01L 23/36; H05K 7/20; H05K 1/0209; H01L 23/3731

(57) ABSTRACT

A microelectronic device includes a substrate, a first component thermally coupled to the substrate at a first area, a second component thermally coupled to the substrate at a second area, a heat source thermally coupled to the substrate at a third area, and a thermal sink thermally coupled to the substrate at a fourth area. A thermal path extends from the first, second, and third areas to the fourth area. The thermal path includes a low thermal conductivity region between the fourth area and the first, second, and third areas. A programmable thermal shunt is disposed across the low thermal conductivity region. The programmable thermal shunt is configured in one of a high thermal conductance state or a low thermal conductance state. The thermal conductance state may be changed from the high thermal conductance state to the low thermal conductance state to the other state, or vice versa.

### FIELD OF THE INVENTION

This invention relates to the field of microelectronic devices. More particularly, this invention relates to temperature control of microelectronic devices.

### BACKGROUND OF THE INVENTION

A microelectronic device may contain two components having performance parameters which are sensitive to the temperatures of the respective components, and it may be desirable to control the two components at different temperatures. Providing separate heaters and associated heater controllers for each of the components undesirably increases cost and complexity of the microelectronic device. Providing a single heater and heater controller limits flexibility of controlling the temperatures of both components to a desired degree.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A microelectronic device includes a substrate, a first component that is thermally coupled to the substrate at a first area, a second component that is thermally coupled to the substrate at a second area, a heat source that is thermally coupled to the substrate at a third area, and a thermal sink that is thermally coupled to the substrate at a fourth area. A thermal path extends from the first, second, and third areas to the fourth area. The thermal path includes a low thermal conductivity region between the fourth area and the first, second, and third areas. A programmable thermal shunt is disposed across the low thermal conductivity region.

### BRIEF DESCRIPTION OF THE VIEWS OF THE DRAWINGS

FIG. 1 depicts an example microelectronic device having programmable thermal shunts.

FIG. 2 depicts another example microelectronic device having programmable thermal shunts.

FIG. 3 depicts another example microelectronic device having programmable thermal shunts.

FIG. 4 depicts a further example of programmable thermal shunts of a microelectronic device.

FIG. 5 depicts an example microfabricated alkali vapor sensor having a programmable thermal shunt.

FIG. 6 is a flowchart of an example method of forming a microelectronic device containing a programmable thermal shunt.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

A microelectronic device includes a substrate, which may include semiconductor material, dielectric material, or a combination thereof. A first component of the microelectronic device is thermally coupled to the substrate at a first area. For the purposes of this disclosure, the term “thermally coupled” may be understood wherein a temperature of the first component is positively correlated with a temperature of the substrate at the first location, so that as the temperature of the substrate at the first location rises, the temperature of the first component also rises, and vice versa. The first component may be a separate device that is attached to the substrate, for example by solder or adhesive. Alternatively, the first component may be formed in the substrate. A second component of the microelectronic device is thermally coupled to the substrate at a second area that is proximate to the first area. A heat source of the microelectronic device is thermally coupled to the substrate at a third area proximate to the first area and the second area. A thermal sink, for example a package structure, leadframe, or heatsink, is thermally coupled to the substrate at a fourth area. A thermal path extends from the first, second, and third areas to the fourth area. The thermal path includes a low thermal conductivity region between the fourth area and the first, second, and third areas. A thermal conductivity of the low thermal conductivity region may be less than 10 percent of a thermal conductivity of the substrate between the first area and the second area. A thermal conductivity of the low thermal conductivity region may be less than 0.1 watts/meter-degree kelvin (W/m-° K.).

A programmable thermal shunt is disposed across the low thermal conductivity region. The programmable thermal shunt may be configured in at least two states: a high thermal conductance state and a low thermal conductance state. A thermal conductance of the programmable thermal shunt in the high thermal conductance state is at least ten times a thermal conductance of the programmable thermal shunt in the low thermal conductance state. The programmable thermal shunt may be reversible, that is, the programmable thermal shunt may be capable of changing states from the high thermal conductance state to the low thermal conductance state, and from the low thermal conductance state to the high thermal conductance state. Alternatively, the programmable thermal shunt may be irreversible, that is, the programmable thermal shunt may be capable of only one state change, for example only from the high thermal conductance state to the low thermal conductance state, or only from the low thermal conductance state to the high thermal conductance state.

During operation of the microelectronic device, heat from the heat source flows through the thermal path to the thermal sink at the fourth area, creating a thermal gradient in the substrate at the first and second locations. The thermal gradient provides a temperature differential for the first component relative to the second component. A magnitude of the thermal gradient is affected by the state of the programmable thermal shunt; the magnitude of the thermal gradient is higher when the programmable thermal shunt is in the high thermal conductance state than when the programmable thermal shunt is in the low thermal conductance state. A desired temperature differential for the first component relative to the second component may be attained by identifying the appropriate state of the programmable thermal shunt, and changing the state of the programmable thermal shunt if necessary. Furthermore, the temperatures of the first component and the second component may be adjusted to desired values by selecting the heat provided by the heat source in combination with the appropriate state of the programmable thermal shunt. For example, to raise the temperatures of the first component and the second component together, the heat source may be adjusted to provide more heat. Conversely, to lower the temperatures of the first component and the second component together, the heat source may be adjusted to provide less heat. To increase the temperature differential between the first component and the second component, the programmable thermal shunt may be configured in the high thermal conductance state. Conversely, to decrease the temperature differential between the first component and the second component, the programmable thermal shunt may be configured in the low thermal conductance state.

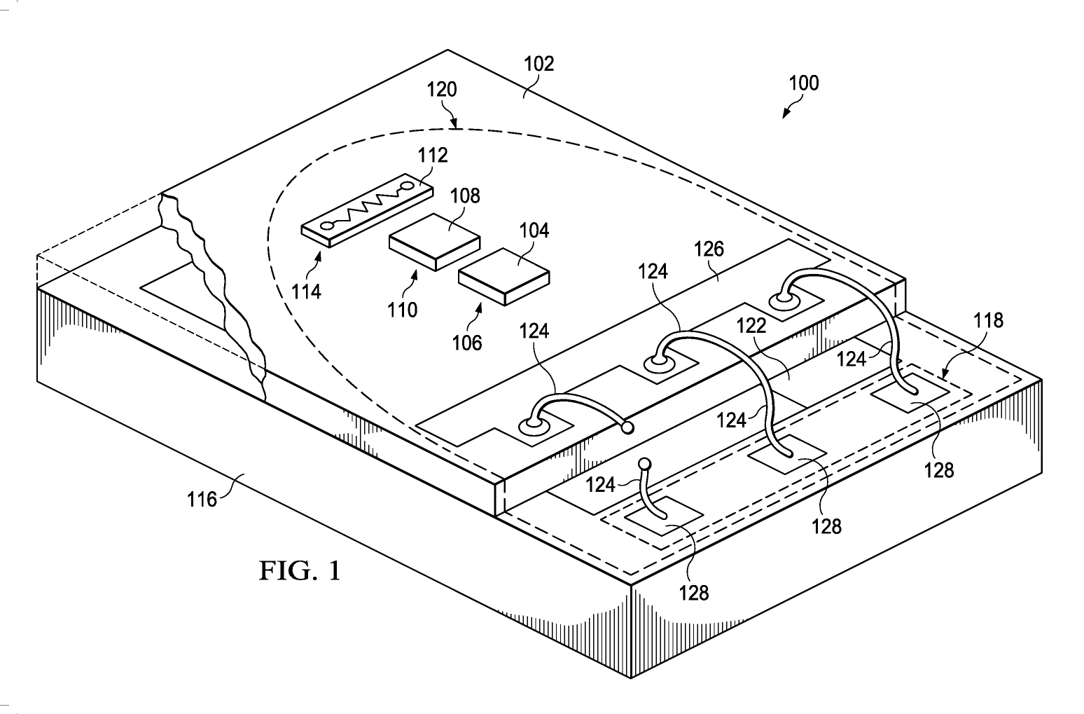

FIG. 1 depicts an example microelectronic device having programmable thermal shunts. The microelectronic device 100 includes a substrate 102, which may include, for example, a semiconductor material, such as silicon or gallium nitride, or a dielectric material, such as glass, ceramic, or sapphire, or a combination thereof. The substrate may have a thermal conductivity greater than 1 W/m-° K., which would be the case for most materials appropriate for the substrate 102. The microelectronic device 100 includes a first component 104 that is thermally coupled to the substrate 102 at a first area 106. In the instant example, the first component 104 may be a separate component that is attached to the substrate at the first area 106, as depicted in FIG. 1. The first component 104 may include, for example, a transistor, an amplifier, a resistor, a laser, or other member having a performance parameter that depends on a temperature of the first component 104. The first component 104 may be attached to the substrate 102 by solder, adhesive, direct molecular bond, anodic bond, or the like. The first area 106 may encompass an area of the substrate 102 contacted by the first component 104 or by material such as solder or adhesive that attaches the first component 104 to the substrate 102.

The microelectronic device includes a second component 108 that is thermally coupled to the substrate 102 at a second area 110. The second component 108 may include a member similar to the first component 104. The second component 108 may be a separate component that is attached to the substrate 102 in a similar manner as the first component 104. The second area 110 may encompass an area the substrate 102 of contact or attachment of the second component 108. The second area 110 is proximate to the first area 106, which, for the purposes of this disclosure, may be understood to mean a lateral separation between the second area 110 and the first area 106 is less than half of a lateral dimension of the substrate 102. For the purposes of this disclosure, the term “lateral” is understood to refer to a direction parallel to a plane of the instant top surface of the substrate of the microelectronic device.

The microelectronic device 100 further includes a heat source 112, which may be a dedicated heater, as depicted schematically in FIG. 1, or a heat-generating component such as a power transistor. The heat source 112 is thermally coupled to the substrate 102 at a third area 114 which is proximate to the first area 106 and the second area 110. The heat source 112 may be a separate component attached to the substrate 102 as depicted in FIG. 1, or may be formed in the substrate 102.

In the instant example, the microelectronic device 100 includes a package member 116. The package member 116 may optionally support the substrate 102 at some areas around a perimeter of the substrate 102 in some manifestations of the instant example, as depicted in FIG. 1. In such manifestations, the substrate 102 and package member 116 are larger than depicted in FIG. 1, so that lateral distances from the first component 104, the second component 108, and the heat source 112 to the areas of the substrate 102 supported by the package member 116 are several times longer than lateral separations between the first component 104, the second component 108, and the heat source 112. The package member 116 of the instant example provides a thermal sink, so that during operation of the microelectronic device 100, heat generated by the heat source 112 flows through the substrate 102, through the package member 116, and on to elements external to the microelectronic device 100. A fourth area 118, depicted in FIG. 1 by a dashed outline, is located at an area of the thermal sink, as provided by the package member 116 in the instant example. It is recognized that the thermal sink may extend outside the fourth area 118.

A thermal path 120, depicted in FIG. 1 by a dashed outline, extends from the first area 106, the second area 110, and the third area 114, to the fourth area 118. The thermal path 120 includes a low thermal conductivity region 122 between the fourth area 118 and the first area 106, the second area 110, and the third area 114. In the instant example, the low thermal conductivity region 122 includes an air gap between the substrate 102 and the package member 116. Air has a thermal conductivity less than 0.05 W/m-° K., which is less than 10 percent of the thermal conductivity the substrate 102.

One or more programmable thermal shunts 124 are disposed across the low thermal conductivity region 122. In the instant example, the programmable thermal shunts 124 may be implemented as bond wires 124 with one end of each bond wire 124 attached to the substrate 102 in the thermal path 120, and another end of each bond wire 124 attached to the package member 116 in the fourth area 118. In one manifestation of the instant example, the bond wires 124 may include round wires of primarily gold, possibly with some beryllium to provide a desired stiffness, having a diameter of 15 microns to 30 microns. In another manifestation, the bond wires 124 may include round wires of primarily copper, possibly with a palladium coating to provide a desired resistance to corrosion, having a diameter of 20 microns to 75 microns. In a further manifestation, the bond wires 124 may include round wires of primarily aluminum, possibly with some silicon or magnesium to provide a desired strength, having a diameter of 17 microns to 100 microns. In other manifestations, gold ribbon, platinum ribbon or aluminum ribbon may be used in place of the gold, copper or aluminum wires.

Each of the programmable thermal shunts 124 may be configured in a high thermal conductance state or a low thermal conductance state. A programmable thermal shunt 124 in the high thermal conductance state has the bond wire 124 intact, or continuous, between the substrate 102 and the package member 116. FIG. 1 depicts two of the programmable thermal shunts 124 in the high thermal conductance state. Conversely, a programmable thermal shunt 124 in the low thermal conductance state has the bond wire 124 severed, or discontinuous, between the substrate 102 and the package member 116. FIG. 1 depicts one of the programmable thermal shunts 124 in the low thermal conductance state. A thermal conductance of the programmable thermal shunt 124 in the high thermal conductance state is at least ten times greater than a thermal conductance of the programmable thermal shunt 124 in the low thermal conductance state. A thermal conductance of the programmable thermal shunt 124 in the high thermal conductance state may be comparable to, or significantly greater than, a thermal conductance of the low thermal conductivity region 122.

The programmable thermal shunts 124 may be initially formed in the high thermal conductance state by a wire bonding operation. One or more of the programmable thermal shunts 124 may be converted to the low thermal conductance state by passing sufficient current through the programmable thermal shunt 124 to cause the material of the wire or ribbon to melt, thus severing the wire or ribbon. A current value needed to melt the wire or ribbon will depend on the material and size of the wire or ribbon. The microelectronic device 100 may include a first bond pad bus 126 on the substrate 102 and second bond pads 128 on the package member 116 for the bond wires 124. The first bond pad bus 126 and the second bond pads 128 may facilitate applying current through the programmable thermal shunts 124. The programmable thermal shunts 124 may optionally be formed concurrently with other wire bonds, not shown, that connect components on the substrate 102 to external terminals of the microelectronic device 100.

In the instant example, the first component 104 is closer to the programmable thermal shunts 124 than the second component 108, and the second component 108 is closer to the programmable thermal shunts 124 than the heat source 112, as shown in FIG. 1. During operation of the microelectronic device 100, a thermal gradient in the substrate 102 may extend from the third location 114 at the heat source 112, past the second location 110 at the second component 108, then past the first location 106 at the first component 104 to the fourth location 118, so that a temperature of the substrate 102 at the second location 110 may be higher than a temperature of the substrate 102 at the first location 106.

In one implementation of the instant example, configuration of the one or more programmable thermal shunts 124 may be determined before operation of the microelectronic device 100. Identification of a desired configuration of the programmable thermal shunts 124 may be achieved, for example, by measurements on similar microelectronic devices, or by thermal modeling of the microelectronic device 100. After the desired configuration of the programmable thermal shunts 124 is identified, appropriate programmable thermal shunts 124 may be converted from the high thermal conductance state to the low thermal conductance state, as described above. Converting one or more of the programmable thermal shunts 124 from the high thermal conductance state to the low thermal conductance state may decrease a temperature difference between the first location 106 and the second location 110.

In another implementation of the instant example, configuration of the one or more programmable thermal shunts 124 may be determined during operation of the microelectronic device 100. Values of performance parameters of the first component 104 and the second component 108 may be obtained, for example by direct measurement or inferred from performance of the microelectronic device 100. One or more of the programmable thermal shunts 124 may be converted from the high thermal conductance state to the low thermal conductance state, and new values of the performance parameters of the first component 104 and the second component 108 may be obtained. Comparison of the values of the performance parameters to desired values may provide guidance for identifying a desired configuration of the programmable thermal shunts 124.

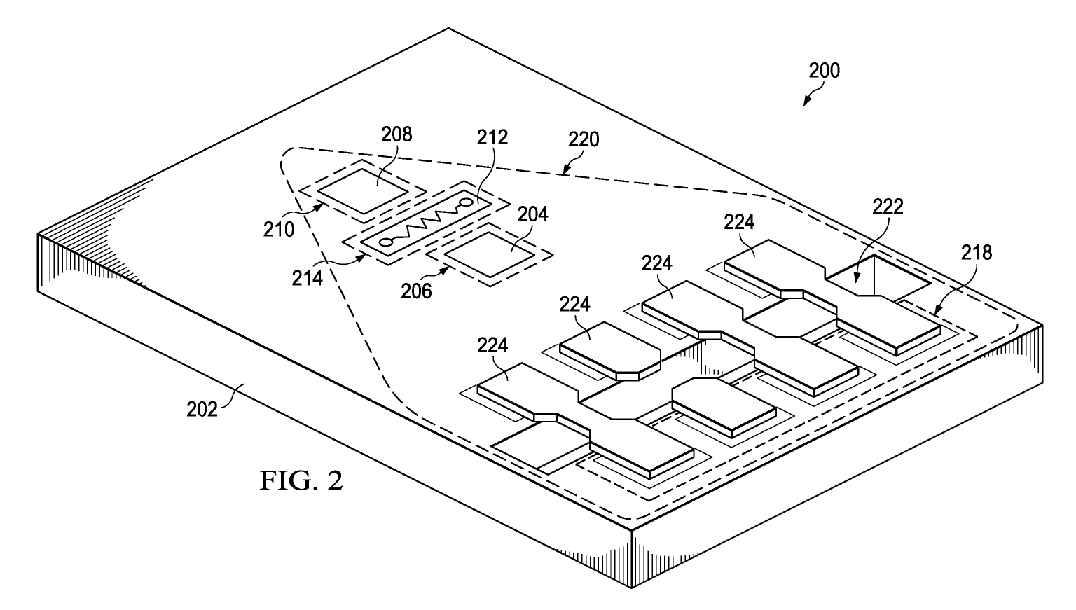

FIG. 2 depicts another example microelectronic device having programmable thermal shunts. The microelectronic device 200 includes a substrate 202, which may include, for example, a semiconductor material, or a dielectric material, or a combination thereof. The substrate may have a thermal conductivity greater than 1 W/m-° K. The microelectronic device 200 includes a first component 204 that is thermally coupled to the substrate 202 at a first area 206. In the instant example, the first component 204 may be formed in the substrate at the first area 206, as depicted in FIG. 2. The first component 204 has a performance parameter that depends on a temperature of the first component 204. The microelectronic device includes a second component 208 that is thermally coupled to the substrate 202 at a second area 210. The second component 208 has a performance parameter that depends on a temperature of the second component 208, and may include a member similar to the first component 204. The second component 208 may be formed in the substrate 202 in a similar manner as the first component 204. The second area 210 is proximate to the first area 206. The microelectronic device 200 further includes a heat source 212, which may be a dedicated heater, as depicted schematically in FIG. 2, or a heat-generating component such as a power transistor. The heat source 212 is thermally coupled to the substrate 202 at a third area 214 which is proximate to the first area 206 and the second area 210. The heat source 212 may be formed in the substrate 202 as depicted in FIG. 2, or may be attached to the substrate 202.

In the instant example, the microelectronic device 200 has a thermal sink in a fourth area 218, depicted in FIG. 2 by a dashed outline. During operation of the microelectronic device 200, heat generated by the heat source 212 flows through the substrate 202, through the thermal sink, and on to elements external to the microelectronic device 200. It is recognized that the thermal sink may extend outside the fourth area 218. A thermal path 220, depicted in FIG. 2 by a dashed outline, extends from the first area 206, the second area 210, and the third area 214, to the fourth area 218. The thermal path 220 includes a low thermal conductivity region 222 between the fourth area 218 and the first area 206, the second area 210, and the third area 214. In the instant example, the low thermal conductivity region 222 includes a trench in the substrate 202 providing an air gap between the fourth area 218 and the first area 206, the second area 210, and the third area 214.

One or more programmable thermal shunts 224 are disposed across the low thermal conductivity region 222. In the instant example, the programmable thermal shunts 224 may be implemented as beam leads 224. One end of each beam lead 224 is attached to the substrate 202 in the thermal path 220 on a side of the low thermal conductivity region 222 closest to the first area 206. Another end of each beam lead 224 is attached to the substrate 202 in the fourth area 218, which is on an opposite side of the low thermal conductivity region 222. In one manifestation of the instant example, the beam leads 224 may include primarily copper. In another manifestation, the beam leads 224 may include primarily gold. In a further manifestation, the beam leads 224 may include primarily aluminum.

Each of the programmable thermal shunts 224 may be configured in a high thermal conductance state or a low thermal conductance state. A programmable thermal shunt 224 in the high thermal conductance state has the beam lead 224 intact, or continuous. FIG. 2 depicts three of the programmable thermal shunts 224 in the high thermal conductance state. Conversely, a programmable thermal shunt 224 in the low thermal conductance state has the beam lead 224 severed, or discontinuous. FIG. 2 depicts one of the programmable thermal shunts 224 in the low thermal conductance state. A thermal conductance of the programmable thermal shunt 224 in the high thermal conductance state is at least ten times greater than a thermal conductance of the programmable thermal shunt 224 in the low thermal conductance state. A thermal conductance of the programmable thermal shunt 224 in the high thermal conductance state may be comparable to, or significantly greater than, a thermal conductance of the low thermal conductivity region 222.

The programmable thermal shunts 224 may be initially formed in the high thermal conductance state by a beam lead bonding operation, such as a tape automated bonding (TAB) operation. One or more of the programmable thermal shunts 224 may be converted to the low thermal conductance state by passing sufficient current through the programmable thermal shunt 224 to cause the material of the beam lead to melt, thus severing the beam lead. A current value needed to melt the beam lead will depend on the material and size of the beam lead.

In the instant example, the first component is closer to the programmable thermal shunts 224 than the heat source 212, and the heat source 212 is closer to the programmable thermal shunts 224 than the second component 208, as shown in FIG. 2. During operation of the microelectronic device 200, a thermal gradient in the substrate 202 may extend from the second location 210 at the second component 208, past the third location 214 at the heat source 212, then past the first location 206 at the first component 204 to the fourth location 218, so that a temperature of the substrate 202 at the second location 210 may be higher than a temperature of the substrate 202 at the first location 206.

In one implementation of the instant example, configuration of the one or more programmable thermal shunts 224 may be determined before operation of the microelectronic device 200. In another implementation, configuration of the programmable thermal shunts 224 may be determined during operation of the microelectronic device 200. Converting one or more of the programmable thermal shunts 224 from the high thermal conductance state to the low thermal conductance state may decrease a temperature difference between the first location 206 and the second location 210.

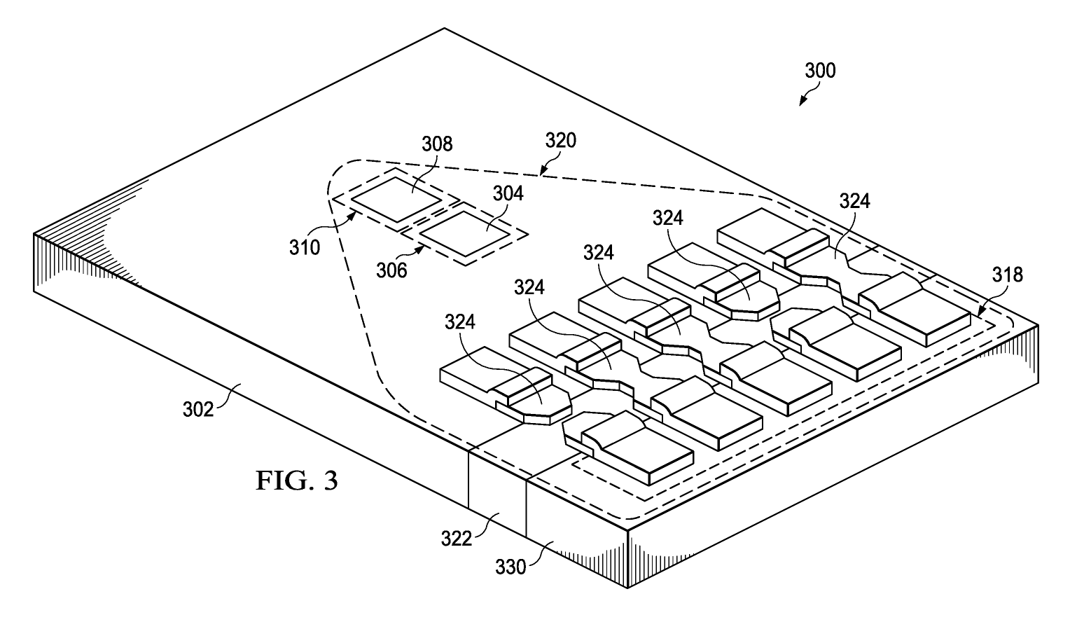

FIG. 3 depicts another example microelectronic device having programmable thermal shunts. The microelectronic device 300 includes a substrate 302. A low thermal conductivity region 322 is located adjacent to the substrate 302. In the instant example, the low thermal conductivity region 322 may include aerogel or other material having a thermal conductivity less than 10 percent of a thermal conductivity of the substrate 302. A thermal sink member 330 is located adjacent to the low thermal conductivity region 322, opposite from the substrate 302. The thermal sink member 330 may be connected to a member located outside of the microelectronic device 300, for example a heatsink, a ground bus, or a chip carrier.

The microelectronic device 300 includes a first component 304 that is thermally coupled to the substrate 302 at a first area 306. The microelectronic device includes a second component 308 that is thermally coupled to the substrate 302 at a second area 310. The second area 310 is proximate to the first area 306. The first component 304 and the second component 308 have performance parameters that depend on temperatures of the substrate 302 at the first area 306 and the second area 310. In the instant example, one or both of the first component 304 and the second component 308 generate heat during operation of the microelectronic device 300, so that the one or both of the first component 304 and the second component 308 provides a heat source of the microelectronic device 300. During operation of the microelectronic device 300, heat generated by the heat source, that is, the one or both of the first component 304 and the second component 308, flows through the substrate 302, through the thermal sink member 330, and on to elements external to the microelectronic device 300.

A thermal path 320, depicted in FIG. 3 by a dashed outline, extends from the first area 306 and the second area 310, to a third area 318 located in the thermal sink member 330. The thermal path 320 includes the low thermal conductivity region 322 between the third area 318 and the first area 306 and the second area 310. One or more programmable thermal shunts 324 are disposed across the low thermal conductivity region 322. In the instant example, the programmable thermal shunts 324 may be implemented as fuses 324. One end of each fuse 324 overlaps and contacts the substrate 302 in the thermal path 320 on a side of the low thermal conductivity region 322 closest to the first area 306. Another end of each fuse 324 overlaps and contacts the thermal sink member 330 in the third area 318. In one manifestation of the instant example, the fuses 324 may include primarily aluminum, formed by an etch process using a photolithographically-defined etch mask. In another manifestation, the fuses 324 may include primarily copper, formed by a damascene process. In another manifestation, the fuses 324 may include polycrystalline silicon, formed by an etch process using a photolithographically-defined etch mask.

Each of the programmable thermal shunts 324 may be configured in a high thermal conductance state, wherein the fuse 324 is continuous across the low thermal conductivity region 322, or a low thermal conductance state, wherein the fuse 324 is discontinuous across the low thermal conductivity region 322. FIG. 3 depicts three of the programmable thermal shunts 324 in the high thermal conductance state, and two of the programmable thermal shunts 324 in the low thermal conductance state. A thermal conductance of the programmable thermal shunt 324 in the high thermal conductance state is at least ten times greater than a thermal conductance of the programmable thermal shunt 324 in the low thermal conductance state. A thermal conductance of the programmable thermal shunt 324 in the high thermal conductance state may be comparable to, or significantly greater than, a thermal conductance of the low thermal conductivity region 322. In one implementation of the instant example, one or more of the programmable thermal shunts 324 may be converted to the low thermal conductance state by passing sufficient current through the programmable thermal shunt 324 to cause the material of the beam lead to melt, thus severing the fuse. In another implementation, one or more of the programmable thermal shunts 324 may be converted to the low thermal conductance state by heating the programmable thermal shunt 324 by a radiant heat process such as a laser to cause the material of the beam lead to melt, thus severing the fuse.

In the instant example, the first component 304 is closer to the programmable thermal shunts 324 than the second component 308, as shown in FIG. 3. During operation of the microelectronic device 300, a thermal gradient in the substrate 302 may extend from the second location 310 at the second component 308, then past the first location 306 at the first component 304 to the fourth location 318, so that a temperature of the substrate 302 at the second location 310 may be higher than a temperature of the substrate 302 at the first location 306. Converting one or more of the programmable thermal shunts 324 from the high thermal conductance state to the low thermal conductance state may decrease a temperature difference between the first location 306 and the second location 310.

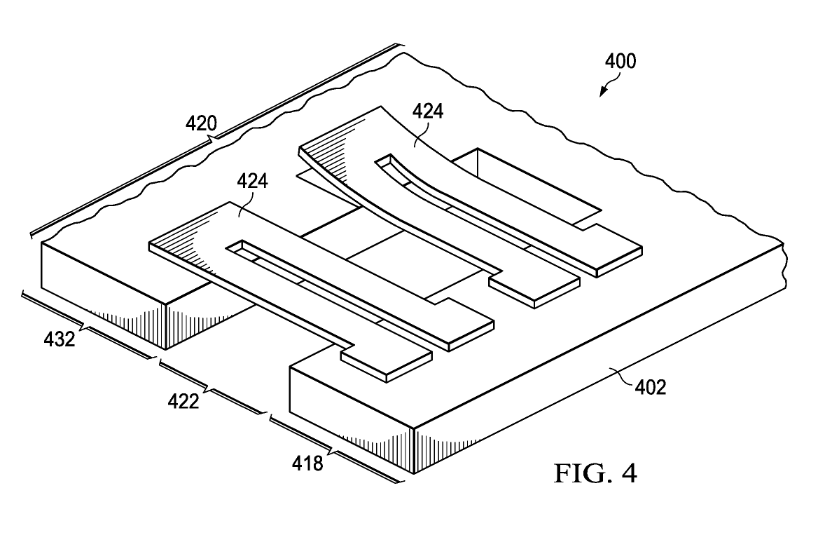

FIG. 4 depicts a further example of programmable thermal shunts of a microelectronic device. The microelectronic device 400 includes a substrate 402 having a component region 432, a low thermal conductivity region 422 adjacent to the component region 432, and a thermal sink region 418 adjacent to the low thermal conductivity region 422 opposite from the component region 432. A thermal path 420 extends from the component region 432 through the low thermal conductivity region 422 to a third area 418 in the thermal sink region 418. The thermal path 420 includes a first area at a first component, not shown in FIG. 4, and a second area of a second component, also not shown in FIG. 4, in the component region 432 of the substrate 402.

Programmable thermal shunts 424 are disposed across the low thermal conductivity region 422. In the instant example, the programmable thermal shunts 424 may be implemented as metal cantilevers 424 which are permanently affixed to the substrate 402 on one side of the low thermal conductivity region 422, for example the thermal sink region 418 as depicted in FIG. 4. The metal cantilevers 424 extend over a portion of the component region 432 of the substrate 402 immediately adjacent to the low thermal conductivity region 422. Each programmable shunt 424 may be independently configured to be in contact with the component region 432 of the substrate 402, thus configuring the programmable shunt 424 in a high thermal conductance state, or may be independently configured to be lifted off the component region 432 of the substrate 402, thus configuring the programmable shunt 424 in a low thermal conductance state. FIG. 4 depicts one of the programmable shunts 424 in the high thermal conductance state, and one of the programmable shunts 424 in the low thermal conductance state. The programmable shunts 424 may be configured by piezoelectric actuators, by shape memory alloy actuators, by bimetal actuators, or the like. The programmable shunts 424 may be reversible, that is, may be capable of changing from the high thermal conductance state to the low thermal conductance state, and also from the low thermal conductance state to the high thermal conductance state.

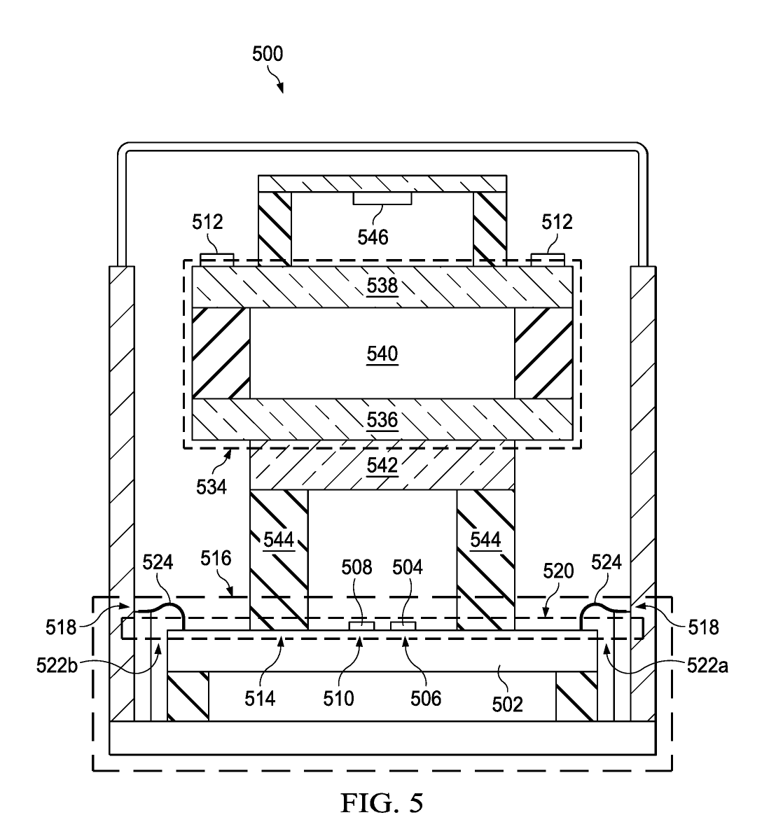

FIG. 5 depicts an example microfabricated alkali vapor sensor having a programmable thermal shunt. The microfabricated alkali vapor sensor 500 includes an alkali vapor cell 534 with a bottom window 536 and a top window 538, and an alkali vapor cavity 540 between the bottom window 536 and the top window 538. Heaters 512 may be mounted on the alkali vapor cell 534 to maintain alkali vapor in the alkali vapor cavity 540 at a desired temperature.

The microfabricated alkali vapor sensor 500 further includes a substrate 502 below the alkali vapor cell 534. The substrate 502 may include, for example, silicon or glass. A first diode laser 504 and a second diode laser 508 are attached, and hence thermally coupled, to the substrate 502, proximate to each other. The first diode laser 504 is thermally coupled to the substrate 502 at a first area 506, which may be an area of attachment material, such as solder or adhesive, between the first diode laser 504 and substrate 502. Similarly, the second diode laser 508 is thermally coupled to the substrate 502 at a second area 510, which may be an area of attachment material between the second diode laser 508 and substrate 502. The substrate 502 is attached to a package member 516 which is part of a package of the microfabricated alkali vapor sensor 500.

An optical element 542, such as a quarter wave plate, is located between the alkali vapor cell 534 and the substrate 502. The first diode laser 504 and the second diode laser 508 are positioned to provide optical signals through the optical element 542 and through the bottom window 536, into the alkali vapor cavity 540. The alkali vapor cell 534 is thermally coupled to the substrate 502 through a standoff 544 at a third area 514. The standoff 544 may include glass or ceramic. A thermal path 520 extends from a fourth area 518 on the package member 516 to the first area 506, the second area 510, and the third area 514. The thermal path 520 extends through a portion of the substrate 502 and through one or more low thermal conductivity regions 522, including a first low thermal conductivity region 522a closer to the first diode laser 504 than to the second diode laser 508, and a second low thermal conductivity region 522b closer to the second diode laser 508 than to the first diode laser 504. The low thermal conductivity regions 522 include air gaps in the instant example. One or more programmable thermal shunts 524 are disposed across the one or more low thermal conductivity regions 522, from the substrate 502 to the fourth area 518. The programmable thermal shunts 524 may include wire bonds, as indicated in FIG. 5, or may include another programmable thermal shunt structure. A first plurality of the programmable thermal shunts 524 may be disposed across the first low thermal conductivity region 522a, and a second plurality of the programmable thermal shunts 524 may be disposed across the first low thermal conductivity region 522b.

A signal detector 546, such as a photodiode, is located above the alkali vapor cell 534. The signal detector 546 is positioned to receive optical signals from the alkali vapor cavity 540, through the top window 538.

During operation of the microfabricated alkali vapor sensor 500, power is applied to the heaters 512 which heats the alkali vapor cell 534. The heat flows from the alkali vapor cell 534, through the standoff 544, to the substrate 502 in the third area 514. The second diode laser 508 emits a pump signal, and the first diode laser 504 emits a probe signal. Wavelengths of the pump signal and the probe signal are desirably adjusted to an absorption wavelength of the alkali vapor. The wavelengths of the first diode laser 504 and the second diode laser 508 may be adjusted by changing the temperature of the substrate 502 at the first area 506 and the second area 510, respectively. The temperature of the substrate 502 at the first area 506 and the second area 510 may be changed by changing thermal conduction states of one or more of the programmable thermal shunts 524. For example, if a higher temperature is desired for the first diode laser 504 than for the second diode laser 508, one or more of the programmable thermal shunt 524 across the first low thermal conductivity region 522a may be changed to a low thermal conductivity state by severing the bond wire in that programmable thermal shunt 524. If a higher temperature is desired for the second diode laser 508 than for the first diode laser 504, one or more of the programmable thermal shunt 524 across the second low thermal conductivity region 522b may be changed to a low thermal conductivity state by severing the bond wire in that programmable thermal shunt 524.

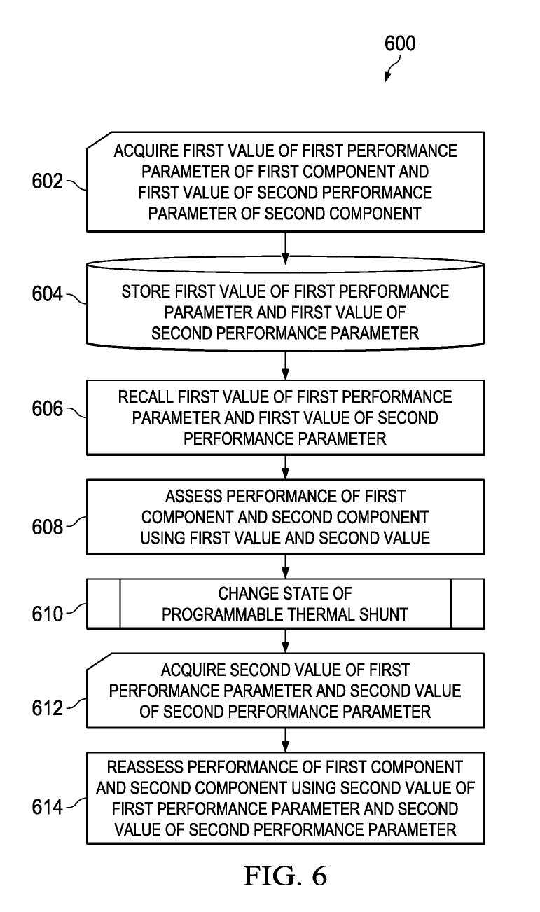

FIG. 6 is a flowchart of an example method of forming a microelectronic device containing a programmable thermal shunt. The method 600 begins with step 602, which includes acquiring a first value of a first performance parameter of a first component of the microelectronic device, and acquiring a first value of a second performance parameter of a second component of the microelectronic device. The first performance parameter and the second performance parameter may depend on temperatures of the first component and the second component, respectively. In one example, the first or second component may include a laser and the first or second performance parameter may be related to a center wavelength of light emitted by the laser. In another example, the first or second component may include a resistor and the first or second performance parameter may be related to a resistance of the resistor. In a further example, the first or second component may include a transistor and the first or second performance parameter may be related to a drive current of the transistor.

Step 604 includes storing the first value of the first performance parameter and the first value of the second performance parameter obtained in step 602. The first value of the first performance parameter and the first value of the second performance parameter may be stored in a computer-readable medium, such as a dynamic random access memory (DRAM), a static random access memory (SRAM), a non-volatile memory such as a flash memory, ferroelectric random access memory (FRAM), or magnetoresistive random access memory (MRAM), a magnetic disk sometimes referred to as a hard disk or hard drive, a removable magnetic diskette sometimes referred to as a floppy diskette, a magnetic tape, or an optical recordable memory medium such as a recordable compact disk (CD-R) or recordable digital video disk (DVD-R). Alternatively, the first value of the first performance parameter and the first value of the second performance parameter may be stored in a human-readable medium, such as a computer display, an instrument display, or printed characters on paper.

Step 606 includes recalling the first value of the first performance parameter and the first value of the second performance parameter that were stored in step 604. The values may be recalled by a computer, if the values were stored in a computer-readable medium in step 604. The values may be recalled, that is, read, by a human if the values were stored in a human-readable medium in step 604.

Step 608 is to assess performance of the first component and the second component using the first value of the first performance parameter and the first value of the second performance parameter that were recalled in step 606. The performance may be assessed using values of other parameters in addition to the first value of the first performance parameter and the first value of the second performance parameter. Assessment of the performance may be attained by comparing the first value of the first performance parameter and the first value of the second performance parameter to target values of the first performance parameter and the second performance parameter, respectively. Assessment of the performance contributes to an estimate of desired adjustments to a temperature differential between the first component and the second component, which leads to a desired configuration of the programmable thermal shunt.

Step 610 includes changing the state of the programmable thermal shunt. Changing the state may be performed, for example, as described in reference to the examples disclosed in reference to FIG. 1 through FIG. 4. States of additional programmable thermal shunts of the microelectronic device may optionally be changed as part of execution of step 610. Changing the state of the programmable thermal shunt to the high thermal conductance state increases the temperature differential between the first component and the second component. Changing the state of the programmable thermal shunt to the low thermal conductance state decreases the temperature differential between the first component and the second component.

Optional step 612 includes acquiring a second value of the first performance parameter and a second value of the second performance parameter. The second values may be obtained in a similar manner to that used to obtain the first values. The second values may be obtained after waiting a sufficient time for a thermal gradient to reach a stable state after changing the state of the programmable thermal shunt in step 610. The second values may be stored, for example as described in reference to step 604, and may be subsequently recalled as described in reference to step 606.

Optional step 614 includes reassessing the performance of the first component and the second component, using the second value of the first performance parameter and the second value of the second performance parameter obtained in step 612. The performance may be reassessed in a similar manner to assessment of the performance in step 608.

The method 600 may be repeated, for example using additional programmable thermal shunts of the microelectronic device. If the programmable thermal shunts are reversible, the method 600 may be repeated to assess various configurations of the states of the programmable thermal shunts to attain a desired performance of the first component and the second component.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

1. A microelectronic device, comprising:
a substrate;
a first component thermally coupled to the substrate at a first area;
a second component thermally coupled to the substrate at a second area proximate to the first area;
a heat source thermally coupled to the substrate at a third area proximate to the first area and the second area;
a thermal sink thermally coupled to the substrate at a fourth area;
a low thermal conductivity region between the fourth area and the first area, the second area, and the third area; and
a programmable thermal shunt disposed across the low thermal conductivity region, the programmable thermal shunt being configurable in a high thermal conductance state and a low thermal conductance state, wherein a thermal conductance of the programmable thermal shunt in the high thermal conductance state is at least ten times a thermal conductance of the programmable thermal shunt in the low thermal conductance state.

2. The microelectronic device of claim 1, wherein the programmable thermal shunt includes a bond wire.

3. The microelectronic device of claim 2, wherein the bond wire comprises a metal selected from the group consisting of gold, copper, and aluminum.

4. The microelectronic device of claim 1, wherein the programmable thermal shunt includes a metal ribbon.

5. The microelectronic device of claim 1, wherein the programmable thermal shunt includes a beam lead comprising a metal selected from the group consisting of copper, gold, and aluminum.

6. The microelectronic device of claim 1, wherein the programmable thermal shunt includes a fuse comprising a material selected from the group consisting of aluminum, copper, and polycrystalline silicon.

7. The microelectronic device of claim 1, wherein the programmable thermal shunt includes a metal cantilever extending across the low thermal conductivity region.

8. The microelectronic device of claim 1, wherein the low thermal conductivity region includes a trench in the substrate.

9. The microelectronic device of claim 1, wherein the low thermal conductivity region includes a gap between the substrate and a package member.

10. The microelectronic device of claim 1, wherein the low thermal conductivity region includes a material with a thermal conductivity less than 10 percent of a thermal conductivity of the substrate.

11. The microelectronic device of claim 1, wherein the low thermal conductivity region includes a material with a thermal conductivity less than 0.1 watts/meter-degree Kelvin (W/m-° K.).

12. The microelectronic device of claim 1, wherein the heat source is separate from the first component and the second component.

13. The microelectronic device of claim 1, wherein the heat source is provided by at least one of the first component and the second component.

14. A method of forming a microelectronic device, comprising:
providing a substrate;
thermally coupling a first component to the substrate at a first area;
thermally coupling a second component to the substrate at a second area;
thermally coupling a heat source to the substrate at a third area;
forming a low thermal conductivity region between a thermal sink and the first area, the second area, and the third area; and
forming a programmable thermal shunt across the low thermal conductivity region of the microelectronic device, the programmable thermal shunt being configurable in a high thermal conductance state and a low thermal conductance state, wherein a thermal conductance of the programmable thermal shunt in the high thermal conductance state is at least ten times a thermal conductance of the programmable thermal shunt in the low thermal conductance state.

15. The method of claim 14, further comprising changing a state of the programmable thermal shunt from the high thermal conductance state to the low thermal conductance state.

16. The method of claim 15, wherein changing the state of the programmable thermal shunt comprises passing current through the programmable thermal shunt.

17. The method of claim 15, wherein changing the state of the programmable thermal shunt comprises heating the programmable thermal shunt by a radiant heat process.

18. A method of forming a microelectronic device, comprising:
acquiring a value of a first performance parameter of a first component of the microelectronic device;
acquiring a value of a second performance parameter of a second component of the microelectronic device;
storing the value of the first performance parameter and the value of the second performance parameter in a computer-readable medium;
recalling the value of the first performance parameter and the value of the second performance parameter from the computer-readable medium;
assessing performance of the first component and the second component using the value of the first performance parameter and the value of the second performance parameter that were recalled; and
changing a thermal conductance state of a programmable thermal shunt of the microelectronic device, the programmable thermal shunt being located across a high thermal conductivity region between a thermal sink region and the first component and the second component.

19. The method of claim 18, wherein changing the thermal conductance state of the programmable thermal shunt comprises exactly one of:
changing the thermal conductance state from a high thermal conductivity state to a low thermal conductivity state; and
changing the thermal conductance state from the low thermal conductivity state to the low thermal conductivity state;
wherein a thermal conductance of the programmable thermal shunt in the high thermal conductance state is at least ten times greater than a thermal conductance of the programmable thermal shunt in the low thermal conductance state.

20. The method of claim 18, wherein the value of the first performance parameter is a first value of the first performance parameter, and the value of the second performance parameter is a first value of the second performance parameter, and further comprising:
acquiring a second value of the first performance parameter;
acquiring a second value of the second performance parameter; and
reassessing performance of the first component and the second component using the second value of the first performance parameter and the second value of the second performance parameter.
